(19) United States
(12) Patent Application Publication
(10) Pub. No.: US 2026/0247724 A1
(43) Pub. Date: Aug. 20, 2026

(54) QUANTUM CASCADE DETECTOR

(71) Applicant: HAMAMATSU PHOTONICS K.K., Hamamatsu-shi (JP)

(72) Inventors: Shohei HAYASHI, Shizuoka (JP); Kazuki HORITA, Shizuoka (JP); Kazuue FUJITA, Shizuoka (JP)

(21) Appl. No.: 19/530,345

(22) Filed: Feb. 5, 2026

(30) Foreign Application Priority Data
Feb. 14, 2025 (JP) 2025-022175

(51) Int. Cl. H10F 39/10; G01J 1/44; H10F 77/124; H10F 77/14; H10F 77/40

(52) U.S. Cl. CPC H10F 39/107; G01J 1/44; H10F 77/1248; H10F 77/146; H10F 77/413; G01J 2001/4446

(57) ABSTRACT

A quantum cascade detector includes a semiconductor substrate and a plurality of unit structures formed on the semiconductor substrate so as to have ridge portions each including an active layer. The unit structures are arranged on a main surface of the semiconductor substrate. Each unit structure includes a contact layer electrically connected to the active layer, an upper metal layer electrically connected to the active layer, and a lower metal layer electrically insulated from the upper metal layer and electrically connected to the contact layer. Each contact layer included in the plurality of unit structures is separated from each other. The upper metal layer of a first unit structure among the plurality of unit structures is electrically connected to the lower metal layer of a second unit structure adjacent to the first unit structure such that the ridge portions of the plurality of unit structures are serially and electrically connected.

### TECHNICAL FIELD

The present disclosure relates to a quantum cascade detector.

### CROSS-REFERENCE TO RELATED APPLICATIONS

This application claims the benefit of priority from Japanese Patent Application No. 2025-022175 filed on Feb. 14, 2025, the entire contents of which are incorporated herein by reference.

### BACKGROUND

Patent Document 1 (Japanese Unexamined Patent Application Publication No. 2017-147428) discloses a quantum cascade detector. In a quantum cascade detector, light is detected using intersubband transition (intersubband absorption) in a quantum well structure.

### SUMMARY

Regarding the quantum cascade detector as described above, there is a need for specifications that have sensitivity in a long wavelength band (for example, 10 μm or more) and are capable of room temperature operation. However, in the long wavelength band, energy between subbands in the quantum well structure becomes narrow, and element resistance of an active layer including the quantum well structure tends to become low. If the element resistance becomes lower than or equal to an input impedance of a readout circuit for reading out a photocurrent from the quantum cascade detector, it becomes difficult for the photocurrent to flow from the quantum cascade detector to the readout circuit. In order to increase the element resistance so that such a problem does not occur, it is necessary to sufficiently cool the quantum cascade detector, which makes it difficult to operate the quantum cascade detector in a high-temperature environment such as room temperature.

As another method for increasing the element resistance, there is a method of increasing the crystal growth film thickness (number of stages) of the quantum well structure constituting the active layer, but due to constraints of semiconductor processes, there is a limit to the film thickness with which the active layer can be formed with high accuracy. Further, although the element resistance can be increased by decreasing the area (ridge width) of the active layer, sensitivity decreases because a light receiving surface becomes small. Further, although the element resistance can be increased by decreasing the absorption length of the active layer, an effect of efficiently absorbing detection target light by guiding the detection target light along the active layer (waveguide effect) is impaired.

As described above, in order to operate the quantum cascade detector in a high-temperature environment such as room temperature, it is necessary to decrease the ridge width or the absorption length of the active layer, but as a result, there has been a problem of a trade-off that sensitivity decreases.

Therefore, an object of one aspect of the present disclosure is to provide a quantum cascade detector capable of suppressing a decrease in sensitivity and realizing operation in a high-temperature environment.

[1] A quantum cascade detector including: a semiconductor substrate; and a plurality of unit structures formed on the semiconductor substrate so as to have ridge portions each configured to include an active layer having a quantum cascade structure, wherein the plurality of unit structures are arranged in a first direction on a main surface of the semiconductor substrate, wherein each of the plurality of unit structures includes: a contact layer provided between the semiconductor substrate and the active layer and electrically connected to the active layer; an upper metal layer provided on a side opposite to the semiconductor substrate with respect to the active layer and electrically connected to the active layer; and a lower metal layer electrically insulated from the upper metal layer and electrically connected to the contact layer, wherein the contact layers included in the plurality of unit structures are separated from each other, and wherein the upper metal layer of a first unit structure among the plurality of unit structures is electrically connected to the lower metal layer of a second unit structure adjacent to the first unit structure among the plurality of unit structures such that the ridge portions of the plurality of unit structures are serially and electrically connected.

In the quantum cascade detector of the above [1], a pseudo multi-stage quantum cascade structure is formed by the plurality of ridge portions (active layers) connected serially and electrically. Thereby, since the element resistance of the quantum cascade detector can be increased, operation in a high-temperature environment such as room temperature can be realized. Further, since the element resistance can be increased by the pseudo multi-stage quantum cascade structure as described above, other methods involving a decrease in sensitivity for increasing the element resistance can be avoided. Therefore, according to the above configuration, it is possible to suppress a decrease in sensitivity and realize operation in a high-temperature environment.

[2] The quantum cascade detector according to [1], wherein the upper metal layer of the first unit structure is formed continuously with the lower metal layer of the second unit structure.

According to the above configuration, between the first unit structure and the second unit structure adjacent to each other, the upper metal layer of the first unit structure and the lower metal layer of the second unit structure can be reliably electrically connected. Thereby, the above-described pseudo multi-stage quantum cascade structure can be reliably formed.

[3] The quantum cascade detector according to [1] or [2], wherein a length of the ridge portion in a direction parallel to the main surface and perpendicular to the first direction is larger than a width of the ridge portion in the first direction.

According to the above configuration, by making the length (absorption length) of the ridge portion in the direction parallel to the main surface and perpendicular to the first direction larger than the width (ridge width) of the ridge portion in the first direction, light absorption efficiency of the active layer can be secured in each unit structure. On the other hand, by suppressing the ridge width to be smaller than the absorption length in each unit structure, the density of the unit structures in the first direction can be increased. This makes it easier to make detection target light incident simultaneously on light receiving surfaces of the plurality of unit structures. That is, since it becomes possible to treat the light receiving surfaces of the plurality of unit structures as one pseudo incident surface, convenience of the quantum cascade detector can be improved.

[4] The quantum cascade detector according to any one of [1] to [3], wherein a groove portion extending in a direction parallel to the main surface and perpendicular to the first direction is provided on the main surface of the semiconductor substrate between the ridge portion of the first unit structure and the ridge portion of the second unit structure so as to divide the contact layer of the first unit structure and the contact layer of the second unit structure.

According to the above configuration, the respective contact layers of the first unit structure and the second unit structure adjacent to each other can be physically and reliably divided by the groove portion. Thereby, it is possible to reliably avoid occurrence of a short circuit between the contact layers adjacent to each other.

[5] The quantum cascade detector according to any one of [1] to [4], wherein each of the plurality of unit structures has a lower cladding layer provided between the active layer and the contact layer, and an upper cladding layer provided between the active layer and the upper metal layer.

According to the above configuration, by providing the upper cladding layer and the lower cladding layer sandwiching the active layer vertically, propagating light can be confined within the active layer, and light absorption can be caused efficiently. Thereby, sensitivity of the quantum cascade detector can be improved.

[6] The quantum cascade detector according to any one of [1] to [5], wherein a texture structure is provided on a back surface of the semiconductor substrate on a side opposite to the main surface.

According to the above configuration, detection target light can be made incident from the back surface of the semiconductor substrate. That is, by refracting and scattering the light incident on the back surface of the semiconductor substrate with the texture structure, light of an electric field component effective for intersubband transition can be made incident on the active layer to cause light absorption.

[7] The quantum cascade detector according to any one of [1] to [6], wherein in an outer unit structure arranged on an outermost side in the first direction among the plurality of unit structures, an end face on the outermost side of the active layer is configured to be exposed.

According to the above configuration, detection target light can be made incident from an end face in an arrangement direction (first direction) of the plurality of unit structures (the end face of the active layer of the outer unit structure).

According to one aspect of the present disclosure, it is possible to provide a quantum cascade detector capable of suppressing a decrease in sensitivity and realizing operation in a high-temperature environment.

### BRIEF DESCRIPTION OF THE DRAWINGS

FIG. 1 is a plan view of a quantum cascade detector of a first embodiment.

FIG. 2 is a cross-sectional view of the quantum cascade detector taken along line II-II of FIG. 1.

FIG. 3 is a cross-sectional view of the quantum cascade detector taken along line III-III of FIG. 1.

FIG. 4 is a cross-sectional view of a quantum cascade detector of a second embodiment.

FIG. 5 is a cross-sectional view of the quantum cascade detector of the second embodiment.

FIG. 6 is a cross-sectional view of a quantum cascade detector of a third embodiment.

FIG. 7 is a side view of a quantum cascade detector of a fourth embodiment.

FIG. 8 is a cross-sectional view of a quantum cascade detector of a fifth embodiment.

### DETAILED DESCRIPTION

Hereinafter, embodiments of the present disclosure will be described in detail with reference to the drawings. In the following description, the same reference numerals are used for the same or corresponding elements, and overlapping description will be omitted. Further, terms such as “upper” and “lower” are for convenience based on the state shown in the drawings. Further, in the drawings, there are portions that are exaggerated in order to explain characteristic portions according to the embodiments in an easy-to-understand manner. Therefore, dimensional ratios of respective parts in the drawings may differ from actual dimensional ratios.

### First Embodiment

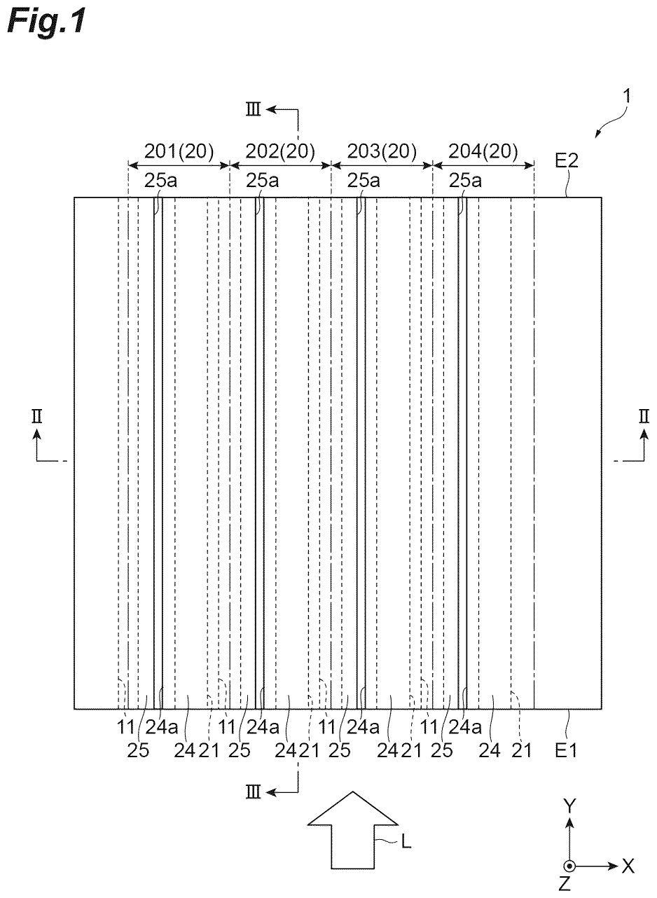

As shown in FIGS. 1 to 3, a quantum cascade detector 1 according to a first embodiment includes a semiconductor substrate 10 and a plurality of unit structures 20 formed on the semiconductor substrate 10. The quantum cascade detector 1 detects detection target light using intersubband transition (intersubband absorption) in a quantum well structure.

The semiconductor substrate 10 is formed in, for example, a rectangular flat plate shape. The semiconductor substrate 10 is, for example, a semi-insulating InP substrate. The semiconductor substrate 10 has a main surface 10a on which the plurality of unit structures 20 are formed, and a back surface 10b on a side opposite to the main surface 10a. The plurality of unit structures 20 are arranged in one direction along the main surface 10a on the main surface 10a. Hereinafter, an arrangement direction of the plurality of unit structures 20 will be described as an X direction (first direction), a thickness direction of the semiconductor substrate 10 will be described as a Z direction (second direction), and a direction perpendicular to the X direction and the Z direction will be described as a Y direction (third direction). Each of the X direction and the Y direction is parallel to the main surface 10a.

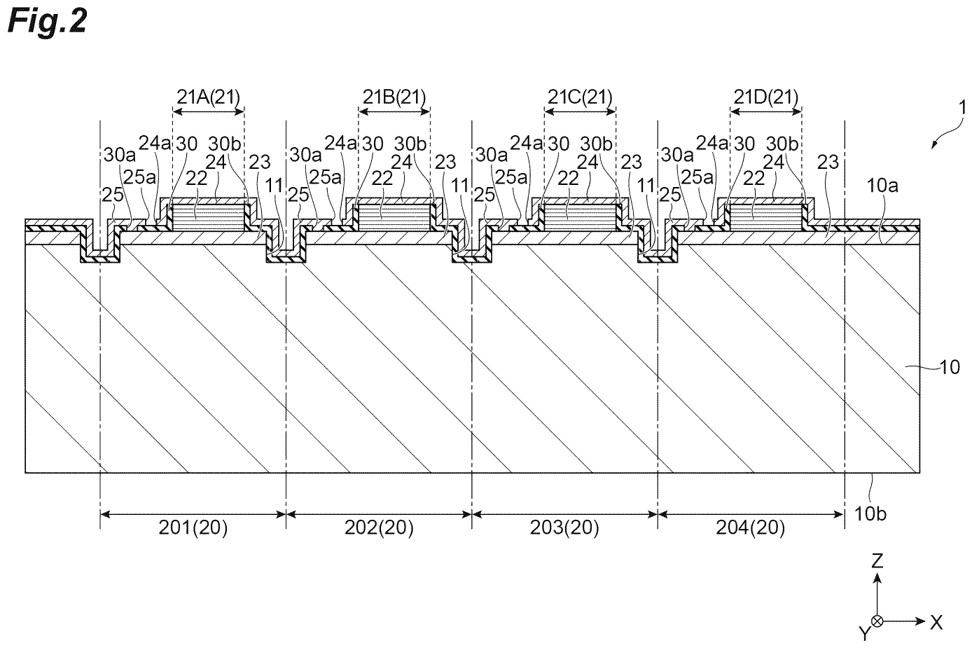

As an example, the plurality of unit structures 20 include four unit structures 201, 202, 203, and 204. The unit structures 201, 202, 203, and 204 are arranged in order along the X direction from the left side to the right side in the drawing in FIGS. 1 and 2. Each unit structure 20 has a ridge portion 21 extending in a stripe shape in the Y direction. The ridge portion 21 is a portion including an active layer 22 in the unit structure 20, and is a portion protruding in the Z direction from the main surface 10a and extending in the Y direction. Hereinafter, the ridge portions 21 of the unit structures 201, 202, 203, and 204 are referred to as ridge portions 21A, 21B, 21C, and 21D, respectively.

The ridge portions 21 (active layers 22) of the plurality of unit structures 20 are serially and electrically connected by a configuration described later. More specifically, the plurality of ridge portions 21A to 21D are connected in a cascade manner along the Y direction. That is, by a connection configuration similar to the connection configuration in which the ridge portion 21A and the ridge portion 21B are electrically connected, the ridge portion 21B and the ridge portion 21C are connected, and the ridge portion 21C and the ridge portion 21D are connected.

The active layer 22 has a cascade structure in which absorption regions (light absorption layers) used for absorption and detection of light and transport regions (electron transport layers) used for transport of electrons serving as carriers are stacked alternately and in multiple stages. For example, in the active layer 22, when a semiconductor laminated structure consisting of n quantum well layers including absorption well layers and n quantum barrier layers is defined as a unit laminate for one period, where n is an integer of 3 or more, this unit laminate is laminated in multiple stages. In the active layer 22, by laminating the above unit laminates in multiple stages, a cascade structure is formed in which the absorption regions including the absorption well layers and detecting detection light by intersubband absorption and the transport regions transporting electrons excited by the intersubband absorption are alternately laminated.

The quantum well layer may be constituted by, for example, an InGaAs layer. The quantum barrier layer may be constituted by, for example, an InAlAs layer. That is, the active layer 22 may be constituted by an InGaAs/InAlAs quantum well structure. As an example, Si which is an n-type impurity is doped into the absorption well layer at a doping density of 5×10¹⁷ cm⁻³ in order to supply electrons serving as carriers.

Each unit structure 20 includes a contact layer 23, an upper metal layer 24, and a lower metal layer 25 in addition to the active layer 22.

The contact layer 23 is provided between the main surface 10a of the semiconductor substrate 10 and the active layer 22, and is electrically connected to the active layer 22. Note that another layer may be provided between the active layer 22 and the contact layer 23 as in a second embodiment described later. A width (length in the X direction) of the contact layer 23 is made larger than a width of the ridge portion 21 (active layer 22). More specifically, the contact layer 23 has a portion extending outward beyond the ridge portion 21 on at least one side (both sides in the present embodiment) in the X direction. As an example, the contact layer 23 is composed of an InGaAs layer having a thickness of 250 nm and an InAlAs layer having a thickness of 0.2 nm. Further, the contact layer 23 functions as a high-concentration doped layer having a higher doping density than the active layer 22. For example, Si which is an n-type impurity is doped into the InGaAs layer of the contact layer 23 at a doping density of 3×10¹⁸ cm⁻.

As shown in FIG. 2, the respective contact layers 23 included in the unit structures 20 are separated from each other. That is, in the unit structures 20 adjacent to each other (for example, the unit structure 201 and the unit structure 202), the contact layer 23 of one unit structure 20 (unit structure 201) is not in physical contact with the contact layer 23 of the other unit structure 20 (unit structure 202).

In the present embodiment, a groove portion 11 extending in the Y direction is formed on the main surface 10a of the semiconductor substrate 10 between the ridge portion 21 of one unit structure 20 and the ridge portion 21 of the other unit structure 20 so as to divide the contact layer 23 of the one unit structure 20 (for example, the unit structure 201) and the contact layer 23 of the other unit structure 20 (for example, the unit structure 202) which are adjacent to each other. The contact layer 23 of each unit structure 20 is provided on a flat portion of the main surface 10a where the groove portion 11 is not formed.

An insulating layer 30 is provided on the main surface 10a of the semiconductor substrate 10 so as to cover an inner surface of the groove portion 11, the contact layer 23, and the ridge portion 21 (active layer 22). An opening portion 30a extending in the Y direction and having a predetermined width in the X direction is provided in a portion of the insulating layer 30 overlapping with an upper surface of the contact layer 23 on one side (left side in FIG. 2) with respect to the ridge portion 21 so as to expose a part of the contact layer 23. Further, an opening portion 30b extending in the Y direction and having a predetermined width in the X direction is provided in the insulating layer 30 so as to expose at least a part of an upper surface of the active layer 22. In the present embodiment, the insulating layer 30 is formed so as to cover side surfaces of the active layer 22 while not covering the upper surface of the active layer 22. That is, the opening portion 30b is formed so as to expose the entire upper surface of the active layer 22.

The upper metal layer 24 is provided on a side opposite to the semiconductor substrate 10 with respect to the active layer 22, and is electrically connected to the active layer 22. Note that another layer may be provided between the active layer 22 and the upper metal layer 24 as in the second embodiment described later. The upper metal layer 24 is provided so as to cover the upper surface of the active layer 22 and the insulating layer 30. The upper metal layer 24 is in contact with the upper surface of the active layer 22 via the opening portion 30b of the insulating layer 30. One end portion 24a (end portion on the left side in FIG. 2) of the upper metal layer 24 is located between the opening portion 30a of the insulating layer 30 and the ridge portion 21. The other end portion (end portion on the right side in FIG. 2) of the upper metal layer 24 of one unit structure 20 is continuously connected to the lower metal layer 25 of another unit structure 20 adjacent to the other side (right side) of the one unit structure 20.

The lower metal layer 25 is electrically insulated from the upper metal layer 24 and electrically connected to the contact layer 23. The lower metal layer 25 is in contact with the upper surface of the contact layer 23 via the opening portion 30a of the insulating layer 30. An end portion 25a (end portion on the right side in FIG. 2) of the lower metal layer 25 on the ridge portion 21 side is separated from the end portion 24a of the upper metal layer 24. Thereby, in the same unit structure 20, the upper metal layer 24 and the lower metal layer 25 are electrically insulated from each other. An end portion of the lower metal layer 25 of one unit structure 20 on a side opposite to the end portion 25a (end portion on the left side in FIG. 2) is continuously connected to the upper metal layer 24 of another unit structure 20 adjacent to one side (left side) of the one unit structure 20.

As shown in FIGS. 1 and 2, in the present embodiment, a portion from the end portion 24a of the upper metal layer 24 of one unit structure 20 (for example, the unit structure 201) to the end portion 25a of the lower metal layer 25 of another unit structure 20 (for example, the unit structure 202) adjacent to the other side (right side) of the one unit structure 20 is configured as one continuous metal layer. The metal layer (the upper metal layer 24 and the lower metal layer 25) may be formed of a metal material such as Au, Cu, or Al, for example.

In the present embodiment, the upper metal layer 24 of the unit structure 201 is formed integrally with the lower metal layer 25 of the unit structure 202, the upper metal layer 24 of the unit structure 202 is formed integrally with the lower metal layer 25 of the unit structure 203, and the upper metal layer 24 of the unit structure 203 is formed integrally with the lower metal layer 25 of the unit structure 204. That is, when focusing on a first unit structure (for example, the unit structure 201) which is one unit structure among the plurality of unit structures 20, the upper metal layer 24 of the first unit structure is electrically connected to the lower metal layer 25 of a second unit structure (for example, the unit structure 202) adjacent to the first unit structure among the plurality of unit structures 20. Thereby, the ridge portions 21 of the plurality of unit structures 20 are serially and electrically connected.

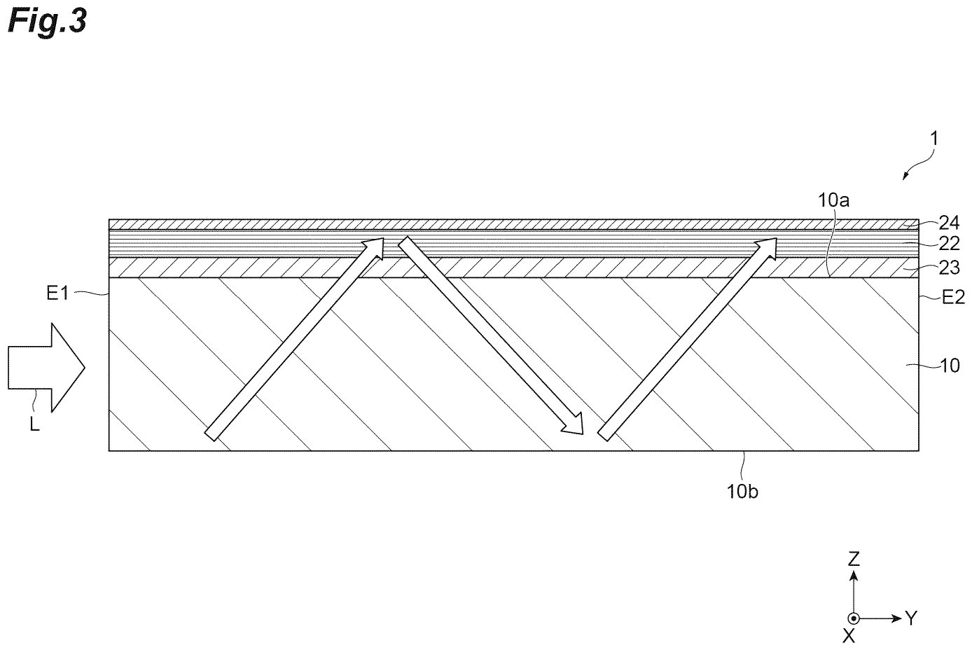

As shown in FIG. 3, in the present embodiment, one end face E1 of the quantum cascade detector 1 in the Y direction serves as an incident surface on which light L (detection target light) to be detected by the quantum cascade detector 1 is incident. Each ridge portion 21 has a waveguide structure constituted by the active layer 22 extending in the Y direction. That is, within a range where the ridge portion 21 (active layer 22) exists in the X direction, the light L incident from the end face E1 travels from the end face E1 to the other end face E2 while repeating total reflection between the upper metal layer 24 and the back surface 10b of the semiconductor substrate 10 (interface between the back surface 10b and an air layer). In this process, the light L is absorbed by the active layer 22, and a photocurrent is generated. Therefore, as the width (ridge width) of the ridge portion 21 (active layer 22) in the X direction is wider, a region (light receiving area) capable of guiding the light L to the active layer 22 becomes larger, and as the length (absorption length) of the ridge portion 21 in the Y direction is longer, the efficiency of the above-described light absorption (that is, efficiency of converting the light L into the photocurrent) is improved.

Generally, in a long wavelength band (for example, 10 μm or more), energy between subbands in the quantum well structure becomes narrow, and the element resistance of the active layer 22 including the quantum well structure tends to become low. If the element resistance becomes lower than or equal to an input impedance of a readout circuit (not shown) for reading out a photocurrent from the quantum cascade detector 1, it becomes difficult for the photocurrent to flow from the quantum cascade detector 1 to the readout circuit.

In a conventional general structure, only one unit structure 20 described in the present embodiment was provided. Alternatively, even if a plurality of unit structures 20 were provided, these plurality of unit structures 20 (ridge portions 21) were not serially and electrically connected. In this case, in order to increase the element resistance of the unit structure 20, there is a method of increasing the crystal growth film thickness of the active layer 22 (that is, the number of stages of the InGaAs/InAlAs quantum well structure described above), but due to constraints of semiconductor processes, there is a limit to the thickness of the active layer 22 that can be formed with high accuracy. Further, although the element resistance can be increased by decreasing the area (ridge width) of the active layer 22, sensitivity decreases because the light receiving surface becomes small. Further, although the element resistance can be increased by decreasing the absorption length (length in the Y direction) of the active layer 22, the waveguide effect as described with reference to FIG. 3 (that is, the effect of efficiently absorbing the light L by guiding the light L along the active layer 22 in the Y direction) is impaired.

On the other hand, in the quantum cascade detector 1, a pseudo multi-stage quantum cascade structure is formed by the plurality of ridge portions 21 (active layers 22) connected serially and electrically. Thereby, since the element resistance of the quantum cascade detector 1 can be increased, operation in a high-temperature environment such as room temperature can be realized. Further, since the element resistance can be increased by the pseudo multi-stage quantum cascade structure as described above (that is, a structure in which the plurality of active layers 22 of the plurality of ridge portions 21A to 21D are stacked in a pseudo multi-stage manner), other methods involving a decrease in sensitivity for increasing the element resistance (for example, a method of shortening the absorption length of each ridge portion 21 or reducing the width of the entire light receiving surface of the plurality of ridge portions 21 (active layer 22) (sum of ridge widths of the respective ridge portions 21A to 21D)) can be avoided. Therefore, according to the quantum cascade detector 1, it is possible to suppress a decrease in sensitivity and realize operation in a high-temperature environment.

More specifically, in the present embodiment, the upper metal layer 24 and the lower metal layer 25 are connected in a cascade manner between the adjacent unit structures 20, and the active layers 22 included in each of the plurality of ridge portions 21A to 21D are electrically connected, whereby one pseudo active layer composed of the plurality of active layers 22 of the plurality of ridge portions 21A to 21D (an active layer including the number of stages obtained by summing the numbers of stages of the respective active layers 22) is formed. That is, according to the quantum cascade detector 1, by forming one pseudo active layer having a large number of stages while suppressing the thickness of each active layer 22 itself (active layer 22 included in each unit structure 20), the element resistance of the entire element formed by the plurality of ridge portions 21A to 21D can be increased. This makes it possible to avoid methods having a trade-off relationship with sensitivity (that is, a method of shortening the absorption length (length in the Y direction) of each ridge portion 21 or reducing the sum of ridge widths of the respective ridge portions 21 (width of the entire light receiving surface)) in order to increase the element resistance. As a result, both high sensitivity performance and room temperature operation can be achieved. According to the quantum cascade detector 1, for example, detection target light in a long wavelength band such as a VLWIR band to a THz band (for example, a wavelength band of 10μm to 3 mm) can be detected with high sensitivity in a room temperature environment.

In the quantum cascade detector 1, in the first unit structure (for example, the unit structure 201) and the second unit structure (for example, the unit structure 202) adjacent to each other, the upper metal layer 24 of the first unit structure is formed continuously with the lower metal layer 25 of the second unit structure. According to the above configuration, between the first unit structure and the second unit structure adjacent to each other, the upper metal layer 24 of the first unit structure and the lower metal layer 25 of the second unit structure can be reliably electrically connected. Thereby, the above-described pseudo multi-stage quantum cascade structure can be reliably formed.

In the quantum cascade detector 1, the length (absorption length) of the ridge portion 21 in the Y direction is larger than the width (ridge width) of the ridge portion 21 in the X direction. According to the above configuration, by making the absorption length of the ridge portion 21 larger than the ridge width, light absorption efficiency of the active layer 22 can be secured in each unit structure 20. On the other hand, by suppressing the ridge width to be smaller than the absorption length in each unit structure 20, the density of the unit structures 20 in the X direction (that is, the number of unit structures 20 included in a range of unit length in the X direction) can be increased. That is, the light receiving surfaces of the plurality of unit structures 20 can be compactly collected in the X direction. This makes it easier to make detection target light incident simultaneously on the light receiving surfaces of the plurality of unit structures 20 (ranges where the ridge portions 21 exist in the X direction in the end face E1). That is, since it becomes possible to treat the light receiving surfaces of the plurality of unit structures 20 as one pseudo incident surface, convenience of the quantum cascade detector 1 can be improved.

In the quantum cascade detector 1, the groove portion 11 extending in the Y direction is provided on the main surface 10a of the semiconductor substrate 10 between the ridge portion 21 of the first unit structure and the ridge portion 21 of the second unit structure so as to divide the contact layer 23 of the first unit structure (for example, the unit structure 201) and the contact layer 23 of the second unit structure (for example, the unit structure 202) adjacent to each other. According to the above configuration, the respective contact layers 23 of the first unit structure and the second unit structure adjacent to each other can be physically and reliably divided by the groove portion 11. Thereby, it is possible to reliably avoid occurrence of a short circuit between the contact layers 23 adjacent to each other.

### Second Embodiment

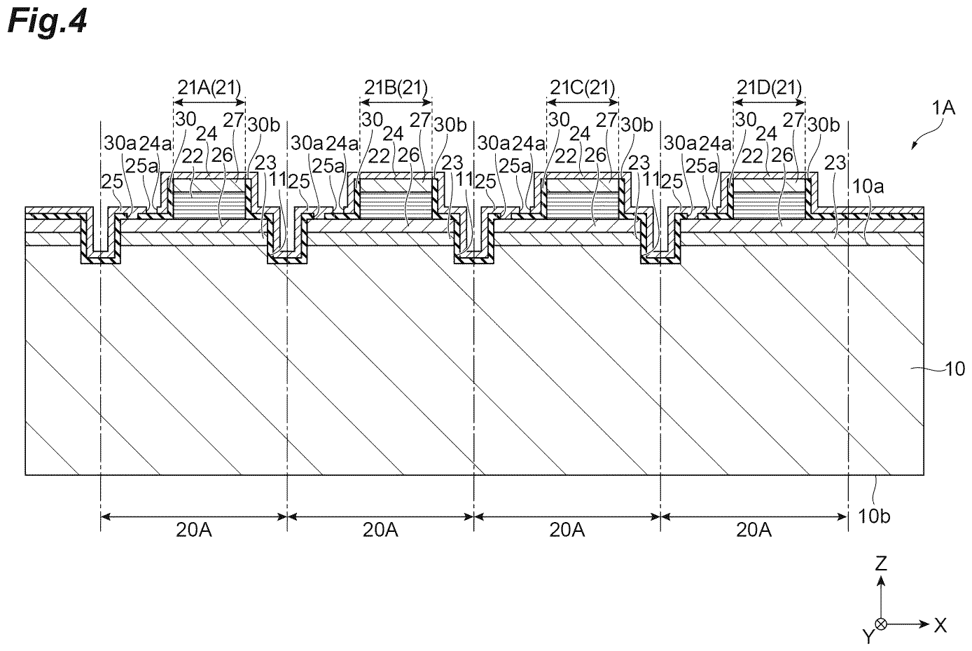

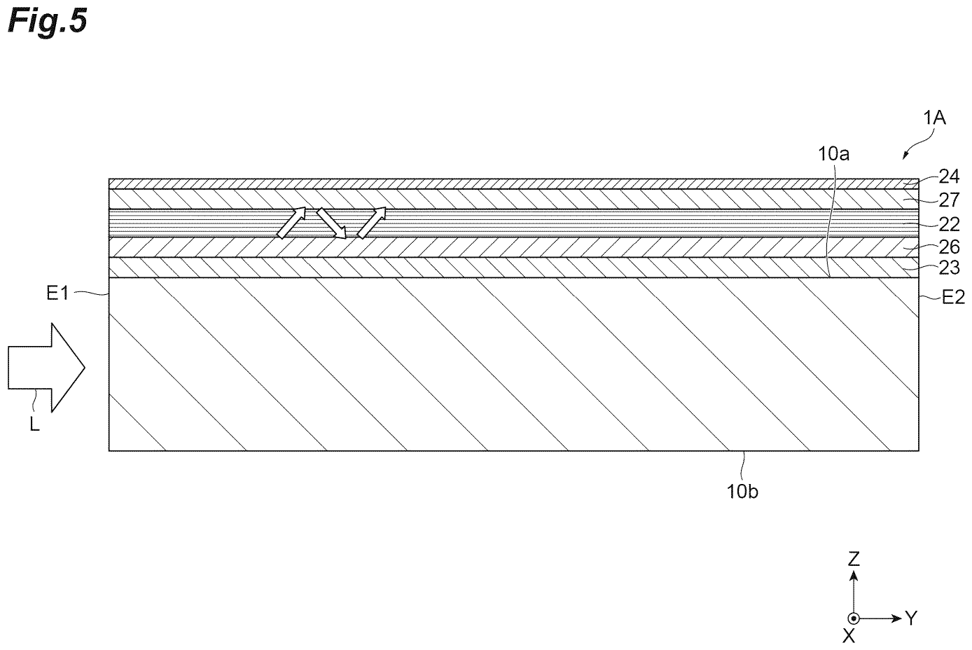

As shown in FIGS. 4 and 5, a quantum cascade detector 1A of a second embodiment is different from the quantum cascade detector 1 in that it has a plurality of unit structures 20A instead of the plurality of unit structures 20. The unit structure 20A is different from the unit structure 20 in that it has a lower cladding layer 26 and an upper cladding layer 27.

The lower cladding layer 26 is provided between the active layer 22 and the contact layer 23. As an example, the lower cladding layer 26 is formed on the entire upper surface of the contact layer 23, and the lower metal layer 25 is in contact with an upper surface of the lower cladding layer 26 via the opening portion 30a of the insulating layer 30. The upper cladding layer 27 is provided between the active layer 22 and the upper metal layer 24. As an example, the upper cladding layer 27 is formed on the entire upper surface of the active layer 22.

The lower cladding layer 26 and the upper cladding layer 27 are low refractive index layers formed of a material having a lower refractive index than the active layer 22 in order to make the active layer 22 function as a core (high refractive index layer). The lower cladding layer 26 and the upper cladding layer 27 are formed of, for example, InP. In each of the lower cladding layer 26 and the upper cladding layer 27, a doping density of impurities (n-type impurities) is, for example, 5×10¹⁶ cm⁻³ or more and 2×10¹⁷ cm⁻³ or less.

According to the quantum cascade detector 1A, by providing the upper cladding layer 27 and the lower cladding layer 26 sandwiching the active layer 22 vertically, as shown in FIG. 5, propagating light can be confined within the active layer 22, and light absorption can be caused efficiently. Thereby, sensitivity of the quantum cascade detector 1A can be improved.

### Third Embodiment

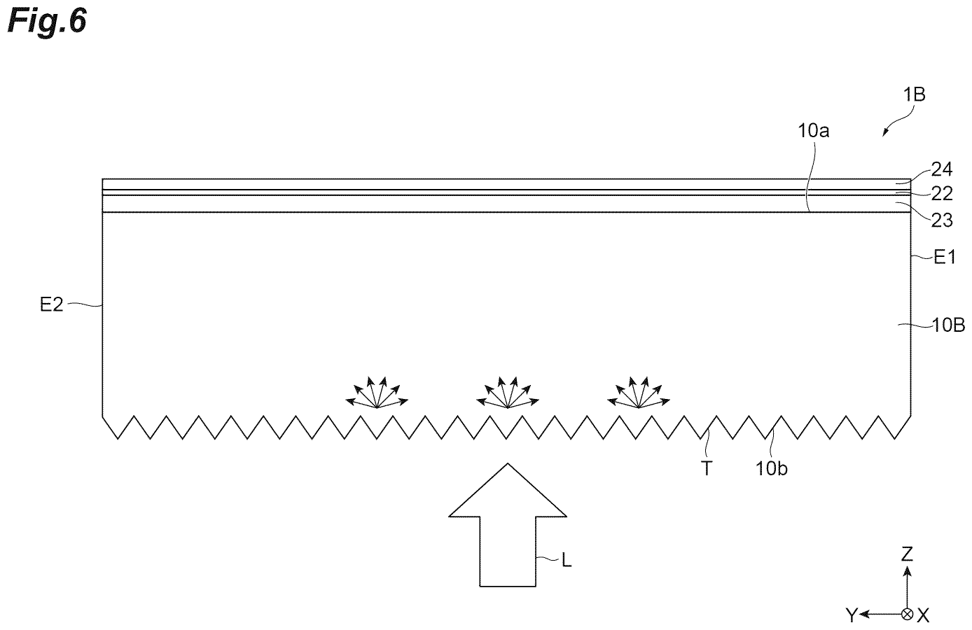

As shown in FIG. 6, a quantum cascade detector 1B of a third embodiment is different from the quantum cascade detector 1 in that it has a semiconductor substrate 10B instead of the semiconductor substrate 10. The semiconductor substrate 10B is different from the semiconductor substrate 10 in that a texture structure T is provided on the back surface 10b. The texture structure T is a concavo-convex structure configured to be capable of generating an electric field component effective for intersubband transition of the active layer 22 by refracting and scattering the detection target light L incident from the back surface 10b. As an example, a concavo-convex height h and a concavo-convex period Γ of the concavo-convex structure can be set in ranges shown in the following formulas (1) and (2). Here, λ is a wavelength of the detection target light L, and n_{sub} is a refractive index of the semiconductor substrate 10B. The concavo-convex height h is a distance in the Z direction between the highest portion (tip portion) of a convex portion and the lowest portion (bottom portion) of a concave portion. The concavo-convex period Γ is a distance along an XY plane between centers of adjacent convex portions (or concave portions) in the XY plane. According to the texture structure T having such a concavo-convex structure, the detection target light L can be suitably scattered.

h ≥λ/2n_{sub} (1)

Γ≥λ/2n_{sub} (2)

According to the quantum cascade detector 1B, the detection target light L can be made incident from the back surface 10b of the semiconductor substrate 10. That is, by refracting and scattering the light incident on the back surface 10b of the semiconductor substrate 10 with the texture structure T, light of an electric field component effective for intersubband transition can be made incident on the active layer 22 to cause light absorption.

### Fourth Embodiment

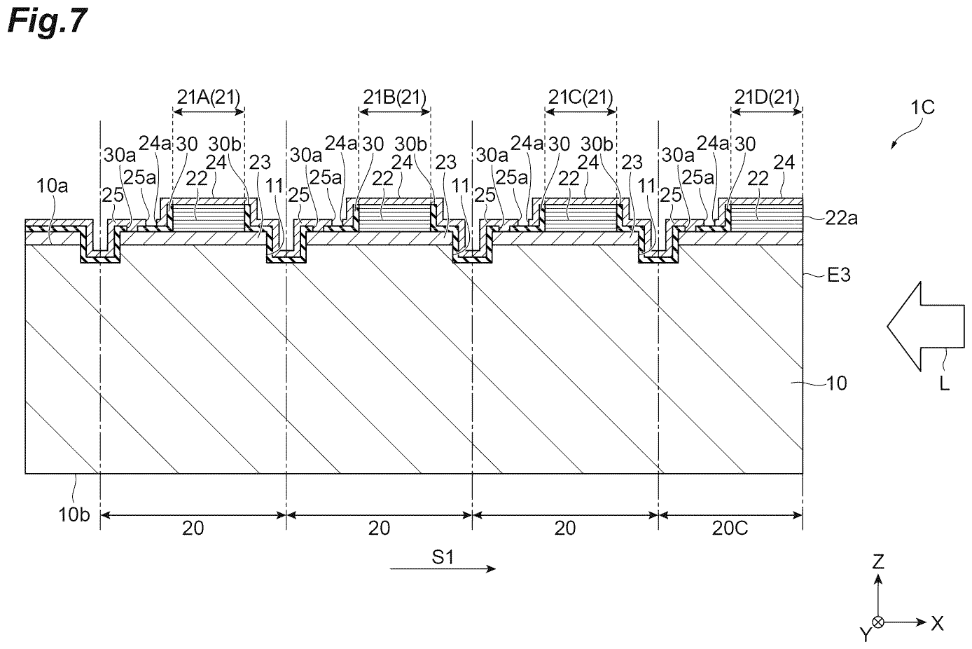

As shown in FIG. 7, a quantum cascade detector 1C of a fourth embodiment is different from the quantum cascade detector 1 in that in an outer unit structure 20C arranged on an outermost side on a first side S1 (right side in the drawing in the example of FIG. 7) in the X direction among the plurality of unit structures 20, an end face 22a on the first side S1 of the active layer 22 is configured to be exposed. As an example, the outer unit structure 20C has a shape in which a portion on the first side S1 of the unit structure 204 of the quantum cascade detector 1 is cut off along a YZ plane such that end faces on the first side S1 of the semiconductor substrate 10, the contact layer 23, the active layer 22, and the upper metal layer 24 are exposed.

According to the quantum cascade detector 1C, the detection target light L can be made incident from an end face in the arrangement direction (X direction) of the plurality of unit structures 20 (the end face 22a of the active layer 22 of the outer unit structure 20C).

### Fifth Embodiment

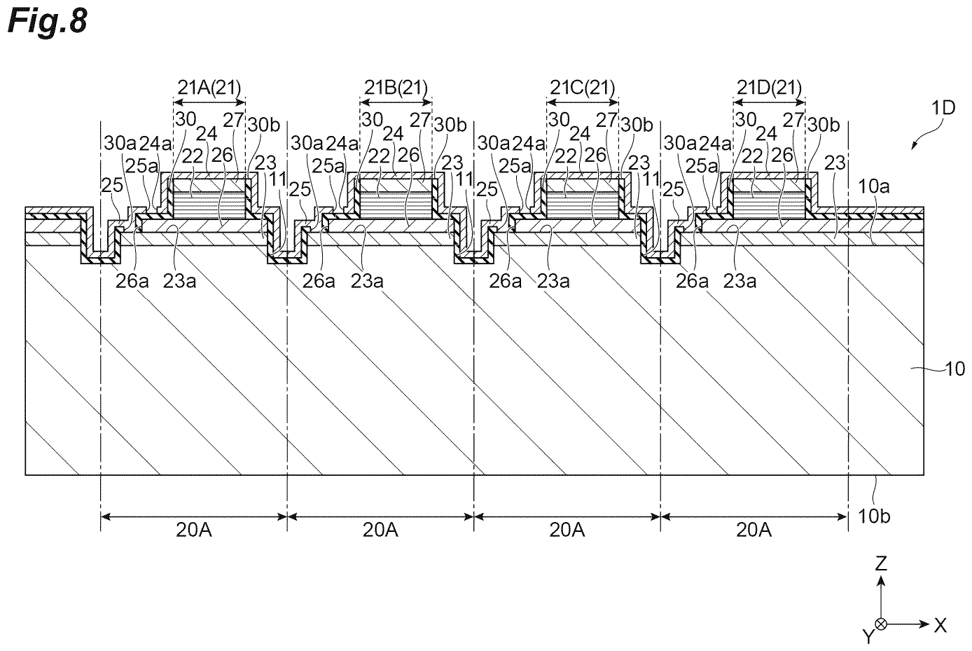

As shown in FIG. 8, a quantum cascade detector 1D of a fifth embodiment matches the quantum cascade detector 1A of the second embodiment in that it has the lower cladding layer 26 and the upper cladding layer 27, but is different from the quantum cascade detector 1A in that the lower metal layer 25 is configured to be in direct contact with the contact layer 23.

In the quantum cascade detector 1D, as an example, in each unit structure 20A, an end portion 26a in the X direction of the lower cladding layer 26 located below the lower metal layer 25 is located inward in the X direction (on the right side in FIG. 8) relative to an end portion of the contact layer 23. The insulating layer 30 is formed so as to cover the end portion 26a. The opening portion 30a of the insulating layer 30 is located above the contact layer 23 on an outer side (left side in FIG. 8) than the end portion 26a. Thereby, the lower metal layer 25 is in contact with an upper surface 23a of the contact layer 23 via the opening portion 30a of the insulating layer 30.

In the quantum cascade detector 1A described above, since the lower metal layer 25 is connected to the contact layer 23 via the lower cladding layer 26, a decrease in sensitivity may occur due to the lower cladding layer 26 acting as a resistance component. On the other hand, in the quantum cascade detector 1D, by bringing the lower metal layer 25 into direct contact with the contact layer 23, sensitivity can be improved as compared with the quantum cascade detector 1A.

### Modifications

Although several embodiments (first embodiment to fifth embodiment) of the quantum cascade detector have been described above, the quantum cascade detector of the present disclosure is not limited to these embodiments. Materials and shapes of respective configurations are not limited to the specific materials and shapes described above, and various materials and shapes other than those described above can be adopted. Further, some configurations included in one embodiment may be omitted or changed as appropriate, and may be arbitrarily combined with configurations included in other embodiments.

In the above embodiment, four unit structures 20 are provided, but the number of the plurality of unit structures 20 is not limited to the above example, and may be two or three, or may be five or more.

In the above embodiment, as shown in FIG. 2, each unit structure 20 is defined by a boundary line passing through a central portion of the groove portion 11 in the X direction, but the plurality of unit structures 20 do not necessarily have to be defined as in the example of FIG. 2. That is, the plurality of unit structures 20 may be defined such that each includes the ridge portion 21, the contact layer 23, the upper metal layer 24, and the lower metal layer 25 described above. Further, between the respective unit structures 20, shapes and dimensions of respective parts may be configured to be identical to each other, or may be configured to be different from each other.

In the above embodiment, between the first unit structure (for example, the unit structure 201) and the second unit structure (for example, the unit structure 202) adjacent to each other, the upper metal layer 24 of the first unit structure and the lower metal layer 25 of the second unit structure are continuously connected in the entire region in the Y direction, but the upper metal layer 24 of the first unit structure and the lower metal layer 25 of the second unit structure may be partially connected.

What is claimed is:

1. A quantum cascade detector comprising:
a semiconductor substrate; and
a plurality of unit structures formed on the semiconductor substrate so as to have ridge portions each configured to include an active layer having a quantum cascade structure,
wherein the plurality of unit structures are arranged in a first direction on a main surface of the semiconductor substrate,
wherein each of the plurality of unit structures includes:
a contact layer provided between the semiconductor substrate and the active layer, and electrically connected to the active layer;
an upper metal layer provided on a side opposite to the semiconductor substrate with respect to the active layer and electrically connected to the active layer; and
a lower metal layer electrically insulated from the upper metal layer and electrically connected to the contact layer,
wherein the contact layers included in the plurality of unit structures are separated from each other, and
wherein the upper metal layer of a first unit structure among the plurality of unit structures is electrically connected to the lower metal layer of a second unit structure adjacent to the first unit structure among the plurality of unit structures such that the ridge portions of the plurality of unit structures are serially and electrically connected.

2. The quantum cascade detector according to claim 1,
wherein the upper metal layer of the first unit structure is formed continuously with the lower metal layer of the second unit structure.

3. The quantum cascade detector according to claim 1,
wherein a length of the ridge portion in a direction parallel to the main surface and perpendicular to the first direction is larger than a width of the ridge portion in the first direction.

4. The quantum cascade detector according to claim 1,
wherein a groove portion extending in a direction parallel to the main surface and perpendicular to the first direction is provided on the main surface of the semiconductor substrate between the ridge portion of the first unit structure and the ridge portion of the second unit structure so as to divide the contact layer of the first unit structure and the contact layer of the second unit structure.

5. The quantum cascade detector according to claim 1,
wherein each of the plurality of unit structures has a lower cladding layer provided between the active layer and the contact layer, and an upper cladding layer provided between the active layer and the upper metal layer.

6. The quantum cascade detector according to claim 1,
wherein a texture structure is provided on a back surface of the semiconductor substrate on a side opposite to the main surface.

7. The quantum cascade detector according to claim 1,
wherein in an outer unit structure arranged on an outermost side in the first direction among the plurality of unit structures, an end face on the outermost side of the active layer is configured to be exposed.
